(19) United States
(12) Patent Application Publication
(10) Pub. No.: US 2026/0171136 A1
(43) Pub. Date: Jun. 18, 2026

(54) MEMORY DEVICE INCLUDING ROW HAMMER DEFENSE LOGIC AND OPERATING METHOD THEREOF

(71) Applicant: Samsung Electronics Co., Ltd., Suwon-si (KR)

(72) Inventors: Eunae Lee, Suwon-si (KR); Jinwoo Seong, Suwon-si (KR); Kijun Lee, Suwon-si (KR); Myungkyu Lee, Suwon-si (KR); Sunghye Cho, Suwon-si (KR); Yejun Ko, Suwon-si (KR); Kyomin Sohn, Suwon-si (KR)

(21) Appl. No.: 19/371,089

(22) Filed: Oct. 28, 2025

(30) Foreign Application Priority Data
Dec. 17, 2024 (KR) 10-2024-0188868

(51) Int. Cl. G11C 11/406

(52) U.S. Cl. CPC G11C 11/40622; G11C 11/40611

(57) ABSTRACT

A memory device includes a memory cell array including an aggressor row, a plurality of victim rows, and a counter configured to store an access count value of the aggressor row, and a row hammer control circuit configured to store care information for the aggressor row based on the access count value and refresh the plurality of victim rows adjacent to the aggressor row in response to a row care command, wherein the row hammer control circuit may include a register configured to store the care information, and a register insertion control circuit configured to store the care information in the register based on a result of comparing the access count value with a threshold.

### CROSS-REFERENCE TO RELATED APPLICATION

This application is based on and claims priority under 35 U.S.C. § 119 to Korean Patent Application No. 10-2024-0188868, filed on Dec. 17, 2024, in the Korean Intellectual Property Office, the disclosure of which is incorporated by reference herein in its entirety.

### BACKGROUND

The inventive concept relates to a memory device including row hammer defense logic and an operating method thereof. In particular, the inventive concept relates to a method for effectively responding to row hammer by preemptively performing a care operation on a certain row according to an access count value of the certain row.

In a system using semiconductor chips, dynamic random access memory (DRAM) is widely used as the system's operational memory or main memory to store data or instructions used by a host within the system and/or to perform a computational operation. Generally, the DRAM writes data or reads written data under control by the host. When the computational operation is performed, the host retrieves instructions and/or data from the DRAM, executes the instructions, and/or uses the data to perform the computation operation. When a result of the computational operation exists, the host writes back the result of the computational operation to the DRAM. Accordingly, the host may require the reliability, availability and serviceability (RAS) attributes of DRAM chips.

To increase the capacity and degree of integration of DRAM, the size of DRAM cells is decreasing. Some DRAM-based systems may experience intermittent failures due to heavy workload. These failures may be caused by repeated access to a single memory cell row, also known as row hammer. Repeated access to a certain row may cause an increased rate of decay in adjacent rows (for example, victim rows) due to electromagnetic coupling. In addition, memory cells connected to the victim rows may experience disturbance, leading to data corruption where memory cell data is flipped.

To prevent or reduce data corruption caused by row hammer, rows may be cared for by performing a refresh on victim rows adjacent to an aggressor row. When it is determined that care is needed for the victim rows adjacent to the aggressor row due to frequent access, a row address of the aggressor row may be stored in a register. However, a method of caring for a row by using a register may not effectively respond to row hammer when the register is full.

### SUMMARY

The inventive concept provides a method of effectively preventing or reducing data corruption caused by row hammer by expanding the range of rows to be cared for using two or more access thresholds and preemptively managing access count values of rows constituting a memory cell array.

The technical objects of the inventive concept are not limited to the technical objects mentioned above, and other technical objects not mentioned herein will be clearly understood by those of ordinary skill in the art from the following description.

According to an aspect of the inventive concept, there is provided a memory device including a memory cell array including an aggressor row, a plurality of victim rows, and a counter that is configured to store an access count value of the aggressor row and includes a plurality of counter memory cells electrically connected to the aggressor row, and a row hammer control circuit that is configured to store care information for the aggressor row based on the access count value and refresh the plurality of victim rows adjacent to the aggressor row in response to a row care command, wherein the row hammer control circuit includes a register configured to store the care information, a comparator configured to compare the access count value with a first threshold and a second threshold and output a comparison result, the first threshold being greater than the second threshold, a register insertion control circuit configured to store the care information in the register based on the comparison result, and a row care control circuit configured to extract the care information from the register in response to the row care command and refresh the plurality of victim rows adjacent to the aggressor row.

According to another aspect of the inventive concept, there is provided an operating method of a memory device including an aggressor row and a plurality of victim rows, the operating method including receiving an active command corresponding to the aggressor row, increasing an access count value of a counter including a plurality of counter memory cells electrically connected to the aggressor row, comparing the access count value with a first threshold, comparing the access count value with a second threshold that is less than the first threshold, storing care information corresponding to the aggressor row in a register based on a result of comparing the access count value with the first threshold and the second threshold, and extracting the care information stored in the register in response to a row care command and refreshing the plurality of victim rows adjacent to the aggressor row.

According to another aspect of the inventive concept, there is provided a memory device including a memory cell array including an aggressor row, a plurality of victim rows, and a counter that is configured to store an access count value of the aggressor row and includes a plurality of counter memory cells electrically connected to the aggressor row, and a row hammer control circuit including a register configured to store care information for the aggressor row, a comparator configured to compare the access count value with a first threshold and a second threshold and output a comparison result, the first threshold being greater than the second threshold, a register monitor configured to monitor a number of elements stored in the register and output the number of elements stored in the register, a random number generator configured to probabilistically generate a random care determination value based on preset probability information and output the random care determination value, a register insertion control circuit configured to store the care information in the register based on the comparison result, the number of elements stored in the register, and the random care determination value, and a row care control circuit configured to extract the care information from the register in response to a row care command and refresh the plurality of victim rows adjacent to the aggressor row.

### BRIEF DESCRIPTION OF THE DRAWINGS

Embodiments will be more clearly understood from the following detailed description taken in conjunction with the accompanying drawings in which:

FIG. 1 is a diagram illustrating a memory system according to an embodiment;

FIGS. 2 and 3 are diagrams illustrating a memory device according to an embodiment;

FIGS. 4 to 6 are diagrams for illustrating a row hammer control circuit according to an embodiment;

FIG. 7 is a diagram for illustrating an aggressor row and a victim row, according to an embodiment;

FIG. 8 is a diagram illustrating a register according to an embodiment;

FIG. 9 is a diagram illustrating a counter according to an embodiment;

FIG. 10 is a flowchart illustrating an operating method of a memory device, according to an embodiment;

FIG. 11 is a flowchart illustrating an operating method of a memory device, according to an embodiment; and

FIG. 12 is a block diagram illustrating a system including a memory device according to an embodiment.

### DETAILED DESCRIPTION OF THE EMBODIMENTS

Embodiments will now be described more fully with reference to the accompanying drawings. The same reference numerals are used to denote the same elements in the drawings, and redundant descriptions thereof will be omitted. As used herein, the term “and/or” includes any and all combinations of one or more of the associated listed items. It is noted that aspects described with respect to one embodiment may be incorporated in different embodiments although not specifically described relative thereto. That is, all embodiments and/or features of any embodiments can be combined in any way and/or combination.

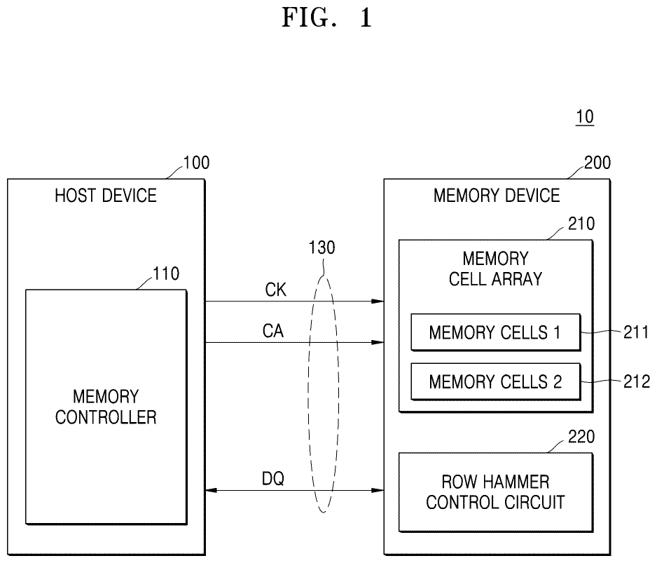

FIG. 1 is a diagram illustrating a memory system 10 according to an embodiment.

Referring to FIG. 1, the memory system 10 may include a host device 100 and a memory device 200.

The host device 100 may include a memory controller 110. The host device 100 may be communicatively connected to the memory device 200 via a memory bus 130.

The host device 100 may be a computing system, such as a computer, a laptop, a server, a workstation, a portable communication terminal, a personal digital assistant (PDA), a portable multimedia player (PMP), a smartphone, or a wearable device. In other embodiments, the host device 100 may be one of components included in a computing system, such as a graphics card.

The host device 100 may correspond to a central processing unit (CPU), a digital signal processor (DSP), a graphics processing unit (GPU), or an application processor (AP), as a functional block that performs a general and/or special purpose computer operation within the memory system 10. The host device 100 may include the memory controller 110 that controls transmission and reception of data to/from the memory device 200.

The memory controller 110 may access the memory device 200 according to a memory request from the host device 100. When the memory controller 110 accesses the memory device 200, it means that the memory controller 110 provides an active command and a row address to the memory device 200.

The memory controller 110 may include a memory physical layer interface (memory PHY) for interfacing with the memory device 200, such as selecting a row and a column which correspond to a memory location, writing data to the memory location, or reading the written data. The memory PHY may include a physical or electrical layer and a logical layer, provided for signals, frequency, timing, driving, detailed operational parameters and functionality used or required for efficient communication between the memory controller 110 and the memory device 200. The memory PHY may support characteristics of DDR and/or LPDDR protocols of a joint electron device engineering council (JEDEC) standard.

The memory controller 110 and the memory device 200 may be connected to each other via the memory bus 130. For the sake of simplicity in the drawing, it is shown that each of a clock signal CK, a command/address CA, and data DQ is provided via a single signal line in the memory bus 130, between the memory controller 110 and the memory device 200, but in practice, may be provided via a plurality of signal lines or a plurality of buses. The signal lines between the memory controller 110 and the memory device 200 may be connected to each other via connectors. The connectors may be implemented as pins, balls, signal lines, or other hardware components.

The clock signal CK may be transmitted from the memory controller 110 to the memory device 200 via a clock signal line of the memory bus 130. A command/address (CA) signal may be transmitted from the memory controller 110 to the memory device 200 via a command/address (CA) bus of the memory bus 130. The data DQ may be transmitted from the memory controller 110 to the memory device 200 or from the memory device 200 to the memory controller 110, via a data (DQ) bus of the memory bus 130, which includes bidirectional signal lines.

The memory device 200 may write the data DQ or read the data DQ and perform a refresh operation, under control by the memory controller 110. For example, the memory device 200 may be a double data rate synchronous dynamic random access memory (DDR SDRAM) device. However, embodiments of the inventive concept are not limited thereto, and the memory device 200 may be any one of volatile memory devices, such as low power double date rate (LPDDR) SDRAM, wide I/O DRAM, high bandwidth memory (HBM), and a hybrid memory cube (HMC). The memory device 200 may include a memory cell array 210 and a row hammer control circuit 220.

The memory cell array 210 may include a plurality of word lines, a plurality of bit lines, and a plurality of memory cells formed at intersections of the word lines and the bit lines. Herein, the plurality of memory cells may be categorized into first memory cells 211 and second memory cells 212 for description of some example embodiments. The memory cells of the memory cell array 210 may be volatile memory cells, for example, DRAM cells.

The memory cell array 210 may include counters respectively connected to the word lines. Each of the counters may store an access count of the corresponding word line. Herein, the access count stored in each counter may be referred to as an access count value. The counters may include the second memory cells 212 among the plurality of memory cells included in the memory cell array 210.

In an embodiment, when an access to a word line occurs, an access count value stored in a counter connected to the corresponding word line may be increased (for example, by 1 when one access occurs).

Herein, a row where an access occurs (for example, a row which is a target of an active command) may be referred to as an aggressor row. A row that is physically adjacent to the aggressor row may be referred to as a victim row. In addition, herein, victim rows corresponding to the aggressor row may refer to victim rows that are physically adjacent to the aggressor row.

Herein, the row hammer control circuit 220 may be hardware, firmware, software, or a combination thereof to control or manage row hammer. The firmware and/or software may be embodied in a non-transitory computer readable medium. The firmware and/or software when executed by a processor communicatively coupled to the non-transitory computer readable medium may be configured to perform one or more of the operations described herein with respect to the row hammer control circuit 220. The row hammer control circuit 220 may obtain an access count value of an aggressor row from a counter of the aggressor row. The row hammer control circuit 220 may compare the access count value with a first threshold and a second threshold. In this case, the first threshold may be greater than the second threshold. These two types of thresholds used for comparison with the access count value are provided as examples for description of one or more embodiments herein and are not intended to limit the inventive concept. The number of threshold types may be three or more. In an embodiment, the row hammer control circuit 220 may compare the access count value with a first threshold, a second threshold, and a third threshold. In this case, the first threshold may be greater than the second threshold, and the second threshold may be greater than the third threshold.

The row hammer control circuit 220 may determine the aggressor row as a target to be cared for, based on a result of comparing the access count value with the thresholds, and may store care information related to the aggressor row.

The row hammer control circuit 220 may perform a care operation on victim rows corresponding to the aggressor row, based on a row care command received from the memory controller 110. The care operation may refer to a refresh operation. Herein, the row care command may refer to a refresh command or a refresh management command. In some embodiments, the refresh management command may be referred to as an RFM command. When an access count of a certain row is greater than a certain reference, the RFM command may be issued by the memory controller 110 to selectively refresh the adjacent rows.

In an embodiment, the number of victim rows that are physically adjacent to an aggressor row may vary depending on a blast radius value. The blast radius value may be a preset value stored in the row hammer control circuit 220. Alternatively, the blast radius value may be variably adjusted by the row hammer control circuit 220 depending on the number of times an access count is initialized. For example, when the blast radius value is 1, the victim rows that are physically adjacent to the aggressor row may refer to two victim rows that are closest to the aggressor row. In addition, for example, when the blast radius value is 2, the victim rows that are physically adjacent to the aggressor row may refer to four victim rows that are closest to the aggressor row.

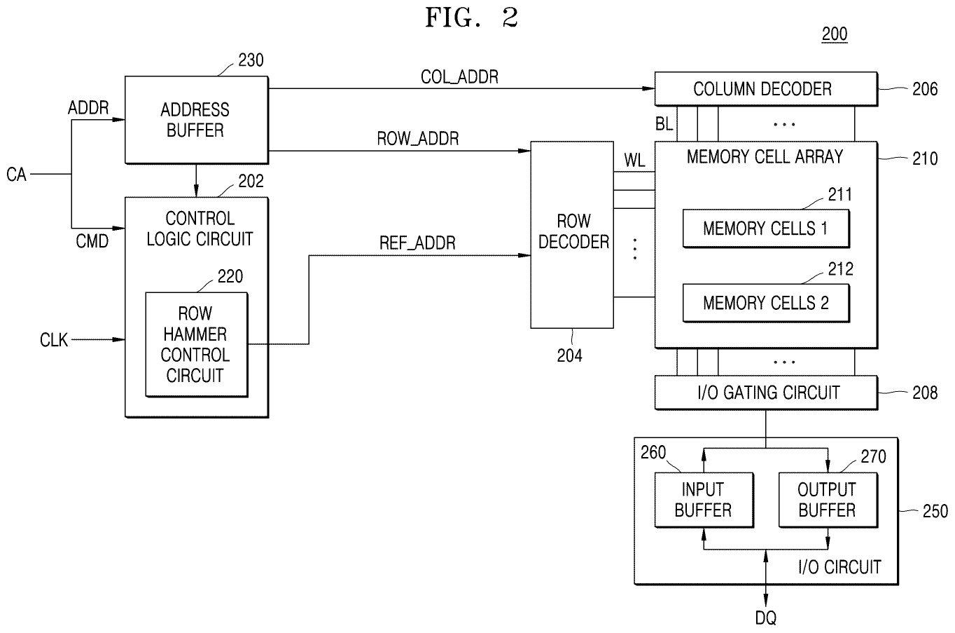

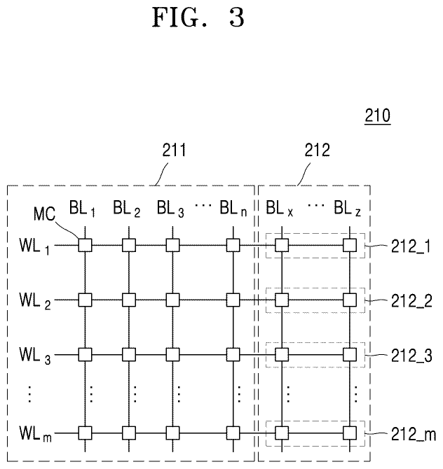

FIGS. 2 and 3 are diagrams illustrating the memory device 200 according to an embodiment. In detail, FIG. 2 illustrates the memory device 200 of FIG. 1, which is implemented as DRAM, and FIG. 3 shows the memory cell array 210 of FIG. 2. FIGS. 2 and 3 may be described with reference to FIG. 1, and redundant descriptions may be omitted.

The DRAM configuration shown in FIG. 2 is provided as an example and does not represent or imply any limitation to the inventive concept.

Referring to FIG. 2, the memory device 200 may include the memory cell array 210, a row decoder 204, a column decoder 206, an input/output gating circuit 208, a control logic circuit 202, an address buffer 230, and an input/output circuit 250. Although not shown in FIG. 2, the memory device 200 may further include a clock buffer, a mode register set (MRS), a bank control logic, and a voltage generating circuit.

The address buffer 230 may receive, from the memory controller 110, an address ADDR including a row address ROW_ADDR and a column address COL_ADDR. The address buffer 230 may provide the received row address ROW_ADDR to the row decoder 204 and provide the received column address COL_ADDR to the column decoder 206.

The memory cell array 210 includes a plurality of memory cells provided in the form of a matrix in which rows and columns are arranged. The memory cell array 210 includes a plurality of word lines WL and a plurality of bit lines BL, which are electrically connected to the memory cells. The plurality of word lines WL may be electrically connected to the rows of the memory cells, and the plurality of bit lines BL may be electrically connected to the columns of the memory cells. Data of memory cells connected to an activated word line may be sensed and amplified by sense amplifiers connected to the plurality of bit lines BL.

The row decoder 204 may decode the row address ROW_ADDR received from the address buffer 230 to select a word line corresponding to the row address ROW_ADDR from among the plurality of word lines WL and electrically connect the selected word line to a word line driver to activate the selected word line.

The column decoder 206 may select certain bit lines BL from among the plurality of bit lines BL of the memory cell array 210. The column decoder 206 may decode an address to generate a column selection signal and electrically connect the bit lines BL selected by the column selection signal to the input/output gating circuit 208.

The input/output gating circuit 208 may include read data latches that store data of the bit lines BL selected by the column selection signal, and a write driver for writing data to the memory cell array 210. The input/output circuit 250 may include a data input buffer 260 and a data output buffer 270. Read data stored in the read data latches of the input/output gating circuit 208 may be provided to the data (DQ) bus via the data output buffer 270. Write data may be written to the memory cell array 210 via the data input buffer 260 connected to the data (DQ) bus and via the write driver of the input/output gating circuit 208.

The control logic circuit 202 may receive a clock signal CK and a command CMD and generate control signals to control an operation timing and/or memory operation of the memory device 200. The control logic circuit 202 may provide the control signals to circuits of the memory device 200. The control logic circuit 202 may read data from the memory cell array 210 and write data to the memory cell array 210, by using the control signals. In FIG. 2, the control logic circuit 202 and the address buffer 230 are shown as separate components, but the control logic circuit 202 and the address buffer 230 may be implemented as a single, inseparable component. In addition, in FIG. 2, the command CMD and the address ADDR are shown as being provided as separate signals, but the address may be considered to be included in the command, as presented in an LPDDR standard, etc.

The control logic circuit 202 may include the row hammer control circuit 220. The row hammer control circuit 220 may provide a refresh address REF_ADDR to the row decoder 204. During a refresh operation of the memory device 200, a row of the memory cell array 210, which has the refresh address REF_ADDR, may be refreshed.

Referring to FIG. 3, in the memory cell array 210, a plurality of memory cells MC may be located at intersections of word lines WL₁ to WLₘ and bit lines BL₁ to BLₙ and BLₓ to BL_{z}. The memory cells MC electrically connected to each of the word lines WL₁ to WLₘ may be categorized into the first memory cells 211 and the second memory cells 212.

The first memory cells 211 electrically connected to each of the word lines WL₁ to WLₘ and the bit lines BL₁ to BLₙ may be memory cells that stores data, and may be referred to as data cells. The second memory cells 212 electrically connected to each of the word lines WL₁ to WLₘ and the bit lines BLₓ to BL_{z} may be memory cells that store access counts of the corresponding word lines WL₁ to WLₘ, and may include counters 212_1, 212_2, 212_3, and 212_m. In some embodiments, the first memory cells 211 may be referred to as data cells, and the second memory cells 212 may be referred to as counter memory cells.

For example, the first counter 212_1 connected to the first word line WL₁ may include a plurality of counter memory cells electrically connected to the first word line WL₁, and may store an access count that activates a memory cell row of the first word line WL₁. Likewise, the second counter 212_2 electrically connected to the second word line WL₂ may include a plurality of counter memory cells electrically connected to the second word line WL₂, and may store an access count that activates a memory cell row of the second word line WL₂. The third counter 212_3 electrically connected to the third word line WL₃ may include a plurality of counter memory cells electrically connected to the third word line WL₃, and may store an access count that activates a memory cell row of the third word line WL₃. Likewise, the m^{th} counter 212_m may include a plurality of counter memory cells connected to the m^{th} word line WLₘ, and may store an access count that activates a memory cell row of the m^{th} word line WLₘ.

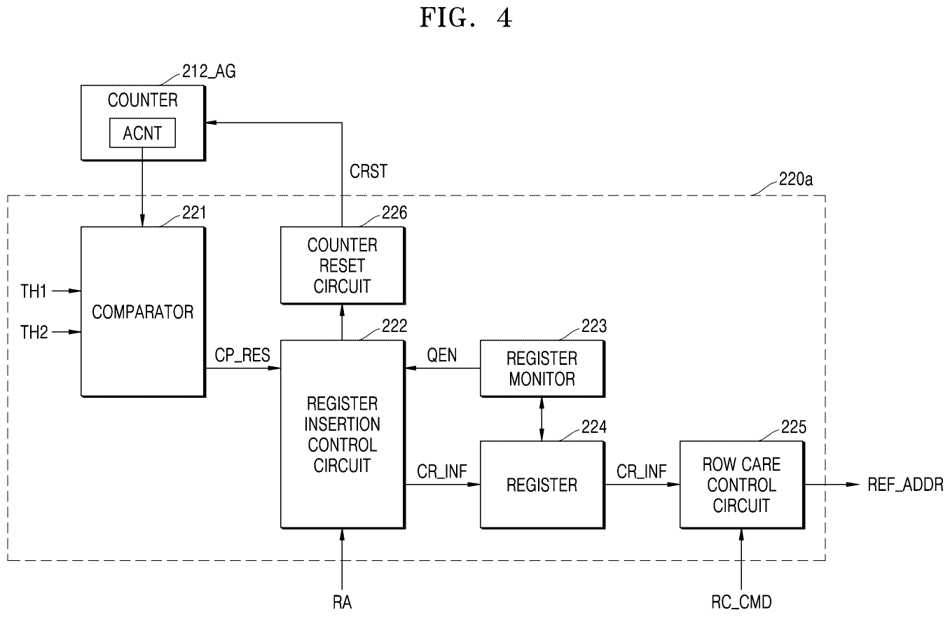

In FIG. 2, the control logic circuit 202 may count the access counts of the respective memory cell rows within the memory cell array 210, and may store the counted access counts in the second memory cells 212 electrically connected to the word lines. The control logic circuit 202 may include the row hammer control circuit 220 that, based on an access count value of each of the rows constituting the memory cell array, determines, as a target to be cared for, a row having an access count that is greater than or equal to a threshold, and that performs a row care operation on the row determined as the target to be cared for. The row hammer control circuit 220 is described in detail with reference to FIG. 4.

In an embodiment, the memory controller 110 may issue a row care command (for example, a refresh command or a refresh management command) for an aggressor row. The memory device 200 may refresh victim rows that are physically adjacent to the aggressor row, in response to the row care command.

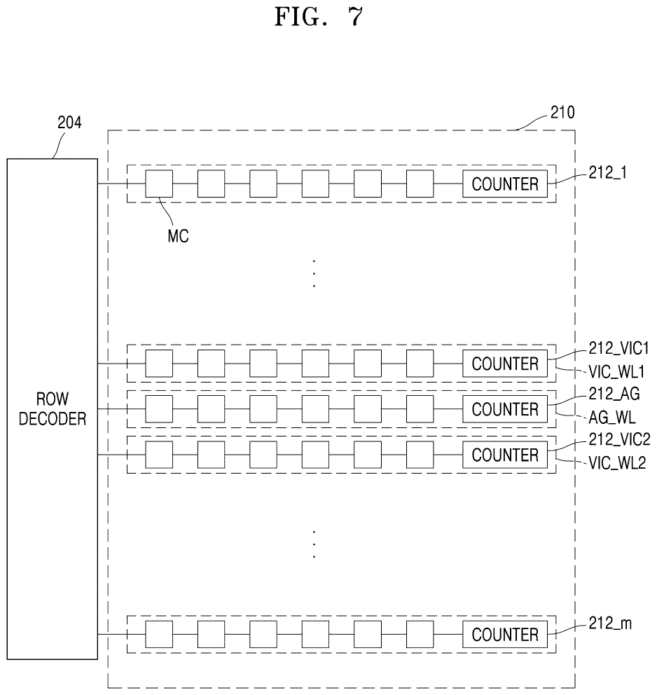

FIGS. 4 to 6 are diagrams for illustrating the row hammer control circuit 220 according to an embodiment. FIG. 7 is a diagram for illustrating an aggressor row and a victim row, according to an embodiment. FIGS. 4 to 7 may be described with reference to FIGS. 1 to 3, and redundant descriptions may be omitted.

For convenience of explanation, FIGS. 4 to 6 illustrate the operation of a row hammer control circuit 220a based on an aggressor row AG_WL and first and second victim rows VIC_WL1 and VIC_WL2 of FIG. 7.

Referring to FIGS. 4 to 7, the row hammer control circuit 220a of FIG. 4 may correspond to the row hammer control circuit 220 of FIG. 1. A counter 212_AG may store an access count value ACNT obtained by counting an access count of the aggressor row AG_WL.

The row hammer control circuit 220a may include a comparator 221, a register insertion control circuit 222, a register monitor 223, a register 224, a row care control circuit 225, and a counter reset circuit 226.

The memory device 200 may receive an active command for the aggressor row AG_WL from the memory controller 110 (of FIG. 1). The control logic circuit 202 of the memory device 200 may update the access count value ACNT stored in the counter 212_AG, in response to the active command. For example, the access count value ACNT stored in the counter 212_AG may be increased by 1. When the access count value ACNT of the counter 212_AG is updated, the counter 212_AG may provide the access count value ACNT to the comparator 221.

The comparator 221 may compare the access count value ACNT received from the counter 212_AG with a first threshold TH1 and a second threshold TH2, and may output a comparison result value CP_RES indicating a result of the comparison. The first threshold TH1 may be greater than the second threshold TH2.

In an embodiment, the comparison result value CP_RES may vary depending on a result of comparing the access count value ACNT with thresholds. For example, when the access count value ACNT is greater than or equal to the first threshold TH1, the comparator 221 may provide a first comparison result value as the comparison result value CP_RES to the register insertion control circuit 222. When the access count value ACNT is less than the first threshold TH1 and greater than or equal to the second threshold TH2, the comparator 221 may provide a second comparison result value as the comparison result value CP_RES to the register insertion control circuit 222. When the access count value ACNT is less than the second threshold TH2, the comparator 221 may provide a third comparison result value as the comparison result value CP_RES to the register insertion control circuit 222.

The register insertion control circuit 222 may receive a row address RA of the aggressor row AG_WL. Care information CR_INF for the aggressor row AG_WL may include the row address RA. The row address RA of the aggressor row AG_WL, which is provided to the register insertion control circuit 222, may result from the memory controller 110 issuing the active command for the aggressor row AG_WL.

The register insertion control circuit 222 may store the care information CR_INF for the aggressor row AG_WL in the register 224 based on the access count value ACNT.

In an embodiment, when the comparison result value CP_RES is the first comparison result value (i.e., when the access count value ACNT is greater than or equal to the first threshold TH1), the register insertion control circuit 222 may store the care information CR_INF for the aggressor row AG_WL in the register 224.

In an embodiment, when the comparison result value CP_RES is the third comparison result value (i.e., when the access count value ACNT is less than the second threshold TH2), the register insertion control circuit 222 may not store the care information CR_INF for the aggressor row AG_WL in the register 224.

The register insertion control circuit 222 may store the care information CR_INF for the aggressor row AG_WL in the register 224 based on the access count value ACNT and a register element count QEN.

In an embodiment, when the comparison result value CP_RES is the second comparison result value (i.e., when the access count value ACNT is less than the first threshold TH1 and greater than or equal to the second threshold TH2) and the register element count QEN received from the register monitor 223 is less than a care reference count, the register insertion control circuit 222 may store the care information CR_INF for the aggressor row AG_WL in the register 224. In this case, the care reference count may be a preset value stored in the register monitor 223. For example, in a case where the comparison result value CP_RES is the second comparison result value and the care reference count is 2, only when the number of elements stored in the register 224 is either zero or one, the register insertion control circuit 222 may store the care information CR_INF for the aggressor row AG_WL in the register 224.

The register monitor 223 may monitor the number of elements stored in the register 224. The register monitor 223 may provide the register element count QEN, which is a result of the monitoring, to the register insertion control circuit 222. Herein, an element stored in the register 224 may correspond to care information for one row of the memory cell array 210.

The register 224 may store, as an element of the register 224, the care information CR_INF received from the register insertion control circuit 222. The register 224 may have a first in first out (FIFO) structure. The register 224 may be implemented by using a plurality of registers. In some embodiments, the register 224 may be referred to as a queue.

In an embodiment, the care information CR_INF may include information about the aggressor row AG_WL, and may include, for example, at least one of a row address of the aggressor row AG_WL, a blast radius value corresponding to the number of victim rows adjacent to the aggressor row AG_WL, and the access count value ACNT stored in the counter 212_AG corresponding to the aggressor row AG_WL.

In an embodiment, it is assumed that three elements are stored in the register 224. For example, the register 224 may include care information for three different aggressor rows within the memory cell array 210. In this case, because the number of elements stored in the register 224 is three, a value provided by the register monitor 223 to the register insertion control circuit 222 may be 3.

In an embodiment, the register 224 may be implemented as a priority queue. When two or more elements are stored in the register 224, the register 224 may prioritize them in descending order from the largest access count. For example, when an access count value of a first aggressor row is 300 and an access count value of a second aggressor row is 512, the second aggressor row may have a higher priority than the first aggressor row. In other words, the second aggressor row may be extracted from the register 224 before the first aggressor row.

The row care control circuit 225 may extract an element stored in the register 224, in response to a row care command RC_CMD. The row care command RC_CMD may be the command CMD provided by the memory controller 110 to the memory device 200. The row care control circuit 225 may generate the refresh address REF_ADDR, which refers to row addresses of rows to be refreshed, based on information indicated by the element extracted from the register 224.

In an embodiment, it is assumed that information of a row, which is indicated by the element extracted from the register 224, is care information related to the aggressor row AG_WL. In this case, rows to be refreshed by the row care command RC_CMD may be the first and second victim rows VIC_WL1 and VIC_WL2 that are physically adjacent to the aggressor row AG_WL. In other words, the row care control circuit 225 may obtain a row address of the aggressor row AG_WL based on the care information CR_INF indicated by the element extracted from the register 224. The row care control circuit 225 may obtain row addresses of the first and second victim rows VIC_WL1 and VIC_WL2 that are physically adjacent to the aggressor row AG_WL, based on the row address of the aggressor row AG_WL.

The row addresses of the first and second victim rows VIC_WL1 and VIC_WL2 may refer to the refresh address REF_ADDR. The row care control circuit 225 may perform a care operation on the first and second victim rows VIC_WL1 and VIC_WL2 based on the refresh address REF_ADDR. In detail, the row care control circuit 225 may refresh the first and second victim rows VIC_WL1 and VIC_WL2 based on the refresh address REF_ADDR.

The counter reset circuit 226 may initialize the access count value ACNT stored in the counter 212_AG.

In an embodiment, a time point at which the counter reset circuit 226 initializes the access count value ACNT stored in the counter 212_AG may be a time point at which the register insertion control circuit 222 stores the care information CR_INF in the register 224.

In an embodiment, the initialization of the access count value ACNT by the counter reset circuit 226 may mean initializing the access count value ACNT to 0.

In an embodiment, the initialization of the access count value ACNT by the counter reset circuit 226 may mean initializing the access count value ACNT to a random value. In this case, the counter reset circuit 226 may generate a random value to be stored in the access count value ACNT.

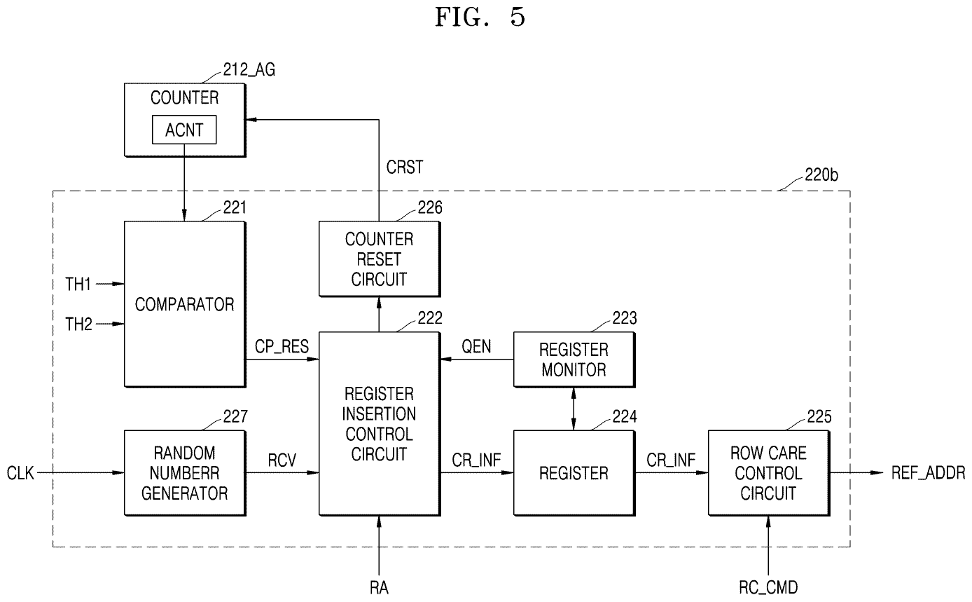

Referring to FIGS. 5 and 7, a row hammer control circuit 220b of FIG. 5 may correspond to the row hammer control circuit 220 of FIG. 1.

Unlike the row hammer control circuit 220a of FIG. 4, the row hammer control circuit 220b of FIG. 5 may further include a random number generator 227. Hereinafter, differences from FIG. 4 are mainly described.

The random number generator 227 may operate based on the clock signal CK provided from the memory controller 110. The random number generator 227 may probabilistically output a random care value RCV. The random care value RCV may be generated according to probability information preset and stored in the random number generator 227. The random number generator 227 may control the register insertion control circuit 222 to probabilistically store the care information CR_INF in the register 224.

In an embodiment, it is assumed that the probability of the random number generator 227 outputting the random care value RCV is p. The value p may be a value indicated by the probability information stored in the random number generator 227, and p may be a real number between 0 and 1. When the access count value ACNT is less than the first threshold TH1 and greater than or equal to the second threshold TH2, the register element count QEN received from the register monitor 223 is less than the care reference count, and the random number generator 227 outputs the random care value RCV according to the probability p, the register insertion control circuit 222 may determine to store the care information CR_INF in the register 224 and store the care information CR_INF in the register 224.

In an embodiment, it is assumed that the probability of the random number generator 227 not outputting the random care value RCV is 1−p. In a case where the random number generator 227 does not output the random care value RCV according to the probability 1−p, even when the access count value ACNT is less than the first threshold TH1 and greater than or equal to the second threshold TH2 and the register element count QEN received from the register monitor 223 is less than the care reference count, the register insertion control circuit 222 may determine not to store the care information CR_INF in the register 224.

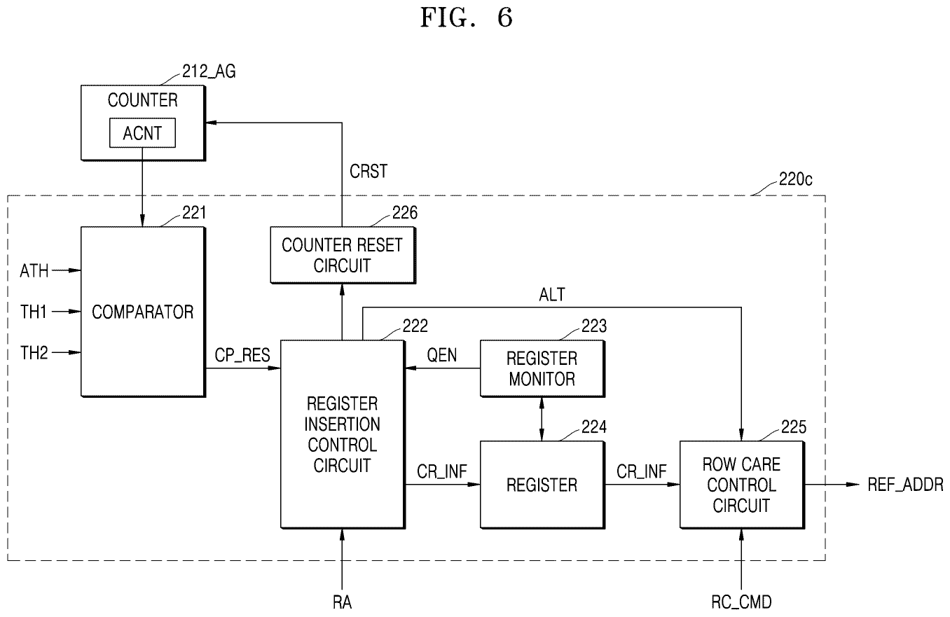

Referring to FIGS. 6 and 7, a row hammer control circuit 220c of FIG. 6 may correspond to the row hammer control circuit 220 of FIG. 1.

Unlike the row hammer control circuit 220a of FIG. 4 and the row hammer control circuit 220b of FIG. 5, in the row hammer control circuit 220c of FIG. 6, the comparator 221 may perform an operation of comparing the access count value ACNT not only with the first threshold TH1 and the second threshold TH2, but also with an alert reference value ATH. The alert reference value ATH may be greater than the first threshold TH1. Hereinafter, differences from FIGS. 4 and 5 are mainly described.

The comparator 221 may compare the access count value ACNT received from the counter 212_AG with the alert reference value ATH. When the access count value ACNT is greater than the alert reference value ATH, the comparator 221 may provide a fourth comparison result value as the comparison result value CP_RES to the register insertion control circuit 222. When the access count value ACNT is greater than the alert reference value ATH, it means that the care information CR_INF for the aggressor row AG_WL has not been stored in the register 224 due to the register 224 being full. This may mean that the care operation (refresh) has not been performed on the first and second victim rows VIC_WL1 and VIC_WL2, which are physically adjacent to the aggressor row AG_WL, at an appropriate time point, and thus may mean that immediate care for the first and second victim rows VIC_WL1 and VIC_WL2 is required.

When receiving the fourth comparison result value from the comparator 221, the register insertion control circuit 222 may perform a care operation on the first and second victim rows VIC_WL1 and VIC_WL2, which are physically adjacent to the aggressor row AG_WL, regardless of whether the care information CR_INF is stored in the register 224, by providing an alert signal ALT including the row address of the aggressor row AG_WL to the row care control circuit 225.

Referring to FIG. 7, the memory cell array 210 of FIG. 7 may correspond to the memory cell array 210 of FIGS. 1 to 3.

The memory cell array 210 may include m rows (where m is a natural number of 1 or more). The m rows may include the aggressor row AG_WL, the first victim row VIC_WL1, and the second victim row VIC_WL2. The aggressor row AG_WL may be a target of an active command issued by the memory controller 110. The first victim row VIC_WL1 and the second victim row VIC_WL2 may be physically adjacent to the aggressor row AG_WL.

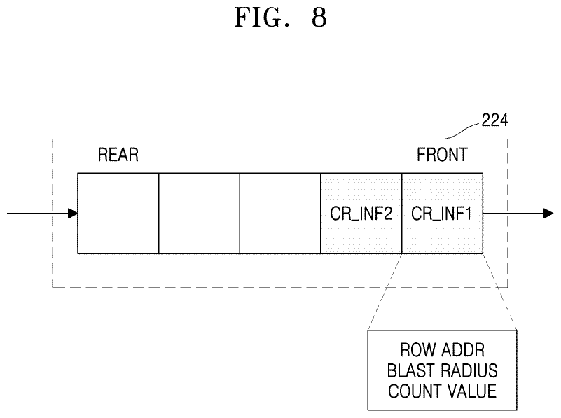

FIG. 8 is a diagram illustrating the register 224 according to an embodiment. FIG. 8 may be described with reference to FIGS. 1 to 7, and redundant descriptions may be omitted.

The register 224 of FIG. 8 stores two elements, with a total capacity of five elements, but this is merely an example for description and is not intended to limit the inventive concept.

Referring to FIG. 8, when storing data in the register 224, the data may be stored in a rear direction of the register 224, and when extracting the data stored in the register 224, the data may be extracted in a front direction of the register 224.

First care information CR_INF1 and second care information CR_INF2 may be stored in the register 224. In some embodiments, rows corresponding to the first care information CR_INF1 and the second care information CR_INF2 may be different from each other. For example, the first care information CR_INF1 may be care information corresponding to the first aggressor row among rows constituting the memory cell array 210. The second care information CR_INF2 may be care information corresponding to the second aggressor row among the rows constituting the memory cell array 210.

In an embodiment, because the number of elements stored in the register 224 is two, the register monitor 223 (of FIG. 4) may provide the register element count QEN indicating 2 to the register insertion control circuit 222.

In an embodiment, the register 224 may be a priority queue. In this case, an access count value of the first care information CR_INF1 may be greater than an access count value of the second care information CR_INF2.

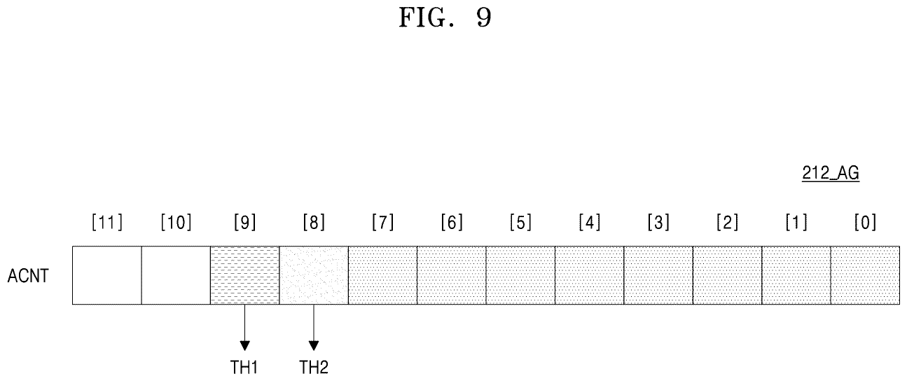

FIG. 9 is a diagram illustrating the counter 212_AG according to an embodiment. FIG. 9 may be described with reference to FIGS. 1 to 8, and redundant descriptions may be omitted.

Referring to FIG. 9, to explain the access count value ACNT stored in the counter 212_AG, it is assumed that the access count value ACNT is 12-bit value, but this is merely an example embodiment for description, and the access count value ACNT may include fewer or more bits.

When access to the aggressor row AG_WL occurs, the access count value ACNT of the counter 212_AG may be increased by the number of access occurrences. For example, when an access to the aggressor row AG_WL occurs once, the access count value ACNT of the counter 212_AG may be increased by 1.

In an embodiment, the access count value ACNT stored in the counter 212_AG may be initialized to 0 or a random value when the memory device 200 is first operated. In this case, the random value may be less than the second threshold TH2.

In an embodiment, the access count value ACNT stored in the counter 212_AG may be initialized to 0 or a random value when the care information CR_INF for the aggressor row AG_WL is stored in the register 224. In this case, the random value may be less than the second threshold TH2.

In an embodiment, it is assumed that the first threshold TH1 and the second threshold TH2 are powers of 2. In this case, the comparator 221 may perform an operation of comparing the access count value ACNT with thresholds, by observing a flip of a certain bit. For example, in a case where the first threshold TH1 is 512(2′b1000000000), when a 10^{th} bit value of the access count value ACNT flips, it may mean that the access count value ACNT is greater than or equal to the first threshold TH1. In addition, for example, in a case where the second threshold TH2 is 256(2′b100000000), when a ninth bit value of the access count value ACNT flips, it may mean that the access count value ACNT is greater than or equal to the second threshold TH2.

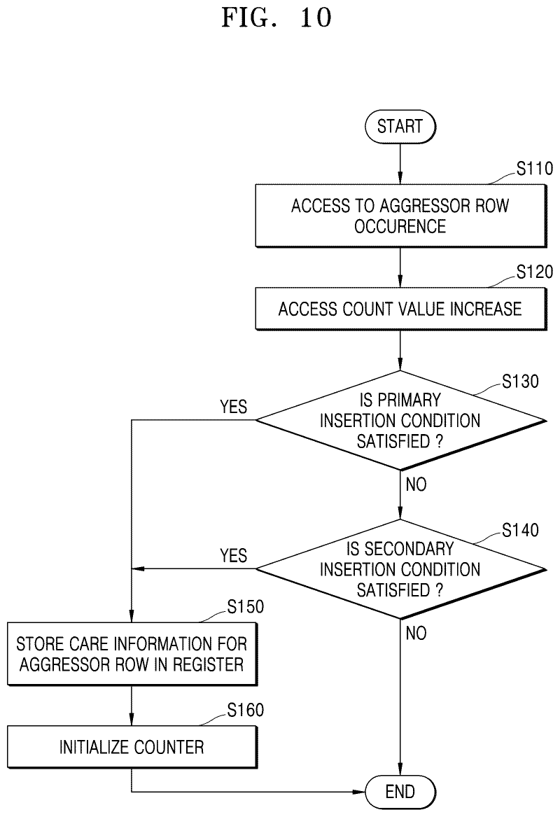

FIG. 10 is a flowchart illustrating an operating method of a memory device, according to an embodiment. FIG. 10 may be described with reference to FIGS. 1 to 9, and redundant descriptions may be omitted.

Referring to FIG. 10, in operation S110, the memory device 200 may receive, from the memory controller 110, an active command issued by the memory controller 110.

In an embodiment, the active command may be a command for performing a read/write operation on the aggressor row AG_WL by accessing the aggressor row AG_WL of the memory device 200.

In operation S120, as the memory device 200 receives the active command, the access count value ACNT stored in the counter 212_AG corresponding to the aggressor row AG_WL may increase. The access count value ACNT may be provided to the row hammer control circuit 220 of the memory device 200.

In operation S130, the memory device 200 may determine whether a primary insertion condition for storing the care information CR_INF corresponding to the aggressor row AG_WL in the register 224 is satisfied. In detail, the memory device 200 may determine whether the access count value ACNT corresponding to the aggressor row AG_WL is greater than or equal to the first threshold TH1.

In an embodiment, when the access count value ACNT is greater than or equal to the first threshold TH1, the memory device 200 may determine to store the care information CR_INF in the register 224.

In an embodiment, when the access count value ACNT is less than the first threshold TH1, the memory device 200 may determine whether a secondary insertion condition according to operation S140 is satisfied.

In operation S140, the memory device 200 may determine whether the secondary insertion condition for storing the care information CR_INF corresponding to the aggressor row AG_WL in the register 224 is satisfied. In detail, the memory device 200 may determine whether the access count value ACNT corresponding to the aggressor row AG_WL is less than the first threshold TH1 and greater than or equal to the second threshold TH2.

In addition, the memory device 200 may determine whether the register element count QEN indicating the number of elements stored in the register 224 is less than a care reference count.

In an embodiment, when the access count value ACNT is less than the first threshold TH1 and greater than or equal to the second threshold TH2 and the register element count QEN is less than the care reference count, the memory device 200 may determine to store the care information CR_INF in the register 224.

In addition, the memory device 200 may determine to store the care information CR_INF in the register 224 according to whether the random care value RCV is generated from the random number generator 227.

In an embodiment, when the access count value ACNT is less than the first threshold TH1 and greater than or equal to the second threshold TH2, the register element count QEN is less than the care reference count, and the random number generator 227 generates the random care value RCV, the memory device 200 may determine to store the care information CR_INF in the register 224.

In operation S150, the memory device 200 may store the care information CR_INF in the register 224 based on a result of the determination in operation S130 or operation S140.

In operation S160, the memory device 200 may initialize the access count value ACNT. In an embodiment, the initialization of the access count value ACNT may be performed when the care information CR_INF is stored in the register 224.

In an embodiment, the access count value ACNT may be initialized to 0 or a random value.

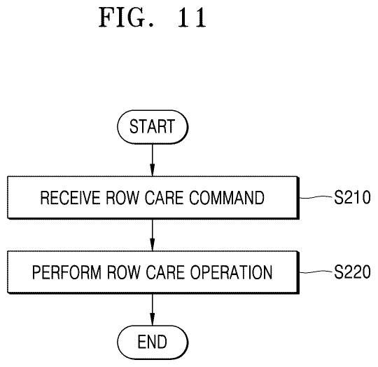

FIG. 11 is a flowchart illustrating an operating method of the memory device 200 according to an embodiment. FIG. 11 may be described with reference to FIGS. 1 to 10, and redundant descriptions may be omitted.

Referring to FIG. 11, in operation S210, the memory device 200 may receive a row care command from the memory controller 110.

In an embodiment, the row care command may be a refresh command or a refresh management command.

In operation S220, the memory device 200 may extract the care information CR_INF stored in the register 224, based on the row care command. The memory device 200 may perform a row care operation by refreshing victim rows that are physically close to the aggressor row AG_WL, based on a row address of the aggressor row AG_WL, which is indicated by the care information CR_INF.

In an embodiment, a row address corresponding to the row care command may match the row address corresponding to the care information CR_INF stored in the register 224.

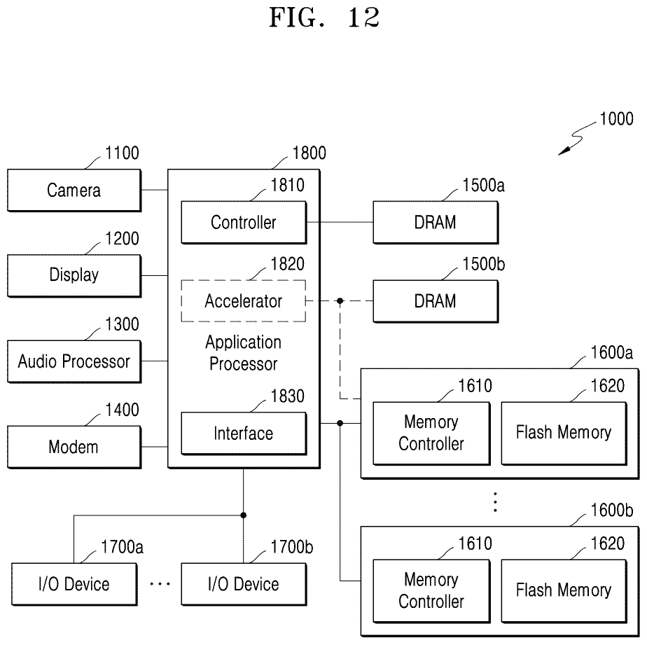

FIG. 12 is a block diagram illustrating a system 1000 including a memory device according to an embodiment.

Referring to FIG. 12, the system 1000 may include a camera 1100, a display 1200, an audio processor 1300, a modem 1400, DRAMs 1500a and 1500b, flash memory devices 1600a and 1600b, I/O devices 1700a and 1700b, and an application processor (hereinafter, referred to as “AP”) 1800. The system 1000 may be implemented as a laptop computer, a mobile phone, a smartphone, a tablet personal computer (PC), a wearable device, a healthcare device, or an Internet of Things (IoT) device. In addition, the system 1000 may be implemented as a server or a PC.

The camera 1100 may capture still images or moving images under control by a user, and may either store captured image/video data or transmit the captured image/video data to the display 1200. The audio processor 1300 may process audio data included in content of the flash memory devices 1600a and 1600b or a network. The modem 1400 may modulate and transmit a signal for wired/wireless data transmission and reception, and demodulate the modulated signal to restore an original signal at a receiving side. The I/O devices 1700a and 1700b may include devices that provide digital input and/or output functions, such as universal serial bus (USB) or storage, a digital camera, a secure digital (SD) card, a digital versatile disc (DVD), a network adapter, and a touch screen.

The AP 1800 may control the overall operation of the system 1000. The AP 1800 may control the display 1200 so that a portion of the content stored in the flash memory devices 1600a and 1600b is displayed on the display 1200. When a user input is received via the I/O devices 1700a and 1700b, the AP 1800 may perform a control operation corresponding to the user input. The AP 1800 may include an accelerator block, which is a dedicated circuit for artificial intelligence (AI) data operations, or may have an accelerator chip 1820 separately from the AP 1800. The DRAM 1500b may be mounted on the accelerator block or the accelerator chip 1820. An accelerator is a functional block that specializes in performing a certain function of the AP 1800. The accelerator may include a GPU which is a functional block that specializes in performing graphic data processing, a neural processing unit (NPU) which is a block that specializes in performing AI calculations and inference, and a data processing unit (DPU) which is a block that specializes in data transmission.

The system 1000 may include the DRAMs 1500a and 1500b. The AP 1800 may control the DRAMs 1500a and 1500b via commands and mode register (MRS) settings that conform to JEDEC standard specifications, or communicate by setting DRAM interface protocols to use company-specific functions such as low voltage/high speed/reliability and cyclic redundancy check (CRC)/error correction code (ECC) functions. For example, the AP 1800 may communicate with the DRAM 1500a via an interface that complies with JEDEC standard specifications such as LPDDR4 and LPDDR5, and the accelerator block or the accelerator chip 1820 may communicate by setting new DRAM interface protocols to control the accelerator-specific DRAM 1500b having a higher bandwidth than the DRAM 1500a.

In FIG. 12, only the DRAMs 1500a and 1500b are illustrated, but the inventive concept is not limited thereto, and any memory, such as PRAM, SRAM, MRAM, RRAM, FRAM, or hybrid RAM, may be used as long as the memory satisfies the bandwidth, response speed, voltage conditions of the AP 1800 or the accelerator chip 1820. The DRAMs 1500a and 1500b may have relatively lower latency and bandwidth than the I/O devices 1700a and 1700b or the flash memory devices 1600a and 1600b. The DRAMs 1500a and 1500b may be initialized at a time point at which the system 1000 is powered on, and may be used as temporary storage locations for an operating system and application data by loading the operating system and the application data, or may be used as execution space for various software code.

In the DRAMs 1500a and 1500b, arithmetic operations such as addition/subtraction/multiplication/division, vector operations, address operations, or fast Fourier transform (FFT) operations may be performed. In addition, in the DRAMs 1500a and 1500b, functions for performing inference may be performed. Herein, the inference may be performed in a deep learning algorithm using an artificial neural network. The deep learning algorithm may include an operation operation of training a model via various data to create a machine-learned model and an inference operation of recognizing data by using the machine-learned model. As an embodiment, an image captured by a user via the camera 1100 may be signal processed and stored in the DRAM 1500b, and the accelerator block or the accelerator chip 1820 may perform AI data operations to recognize data by using data stored in the DRAM 1500b and functions used for inference.

The system 1000 may include a plurality of storages or the flash memory devices 1600a and 1600b, each having a greater capacity than the DRAMs 1500a and 1500b. The accelerator block or the accelerator chip 1820 may perform training operations and AI data operations by using the flash memory devices 1600a and 1600b. In an embodiment, the flash memory devices 1600a and 1600b may more efficiently perform training operations and inference AI data operations performed by the AP 1800 and/or the accelerator chip 1820, by using an operational unit provided within a memory controller 1610. The flash memory devices 1600a and 1600b may store images captured via the camera 1100 or may store data received via a data network. For example, the flash memory devices 1600a and 1600b may store augmented reality/virtual reality, high definition (HD) or ultra high definition (UHD) content.

In the system 1000, the DRAMs 1500a and 1500b may each include a row hammer control circuit as described with reference to FIGS. 1 to 11. The DRAMs 1500a and 1500b may each include a memory cell array including word lines and a plurality of counters and a control logic circuit, wherein the plurality of counters may store access count values of the word lines. The DRAMs 1500a and 1500b may expand the range of rows to be cared for using two or more access thresholds and preemptively manage access count values of rows constituting the memory cell array, thereby effectively preventing data corruption caused by row hammer.

While the inventive concept has been particularly shown and described with reference to embodiments thereof, it will be understood that various changes in form and details may be made therein without departing from the spirit and scope of the following claims.

What is claimed is:

1. A memory device comprising:
a memory cell array comprising an aggressor row, a plurality of victim rows, and a counter that is configured to store an access count value of the aggressor row and comprises a plurality of counter memory cells electrically connected to the aggressor row; and
a row hammer control circuit that is configured to store care information for the aggressor row based on the access count value and refresh the plurality of victim rows adjacent to the aggressor row in response to a row care command,
wherein the row hammer control circuit comprises:
a register configured to store the care information;
a comparator configured to compare the access count value with a first threshold and a second threshold and output a comparison result, the first threshold being greater than the second threshold;
a register insertion control circuit configured to store the care information in the register based on the comparison result; and
a row care control circuit configured to extract the care information from the register in response to the row care command and refresh the plurality of victim rows adjacent to the aggressor row.

2. The memory device of claim 1, wherein the care information comprises a row address of the aggressor row.

3. The memory device of claim 1, wherein the row care command is received by the memory device along with a row address of the aggressor row and includes a refresh command or a refresh management (RFM) command.

4. The memory device of claim 1, wherein the register insertion control circuit is configured to store the care information for the aggressor row in the register when the comparison result indicates that the access count value is greater than the first threshold.

5. The memory device of claim 1, wherein the row hammer control circuit further comprises a register monitor configured to monitor a number of elements stored in the register and provide the number of elements stored in the register to the register insertion control circuit, and
wherein the register insertion control circuit is further configured to store the care information for the aggressor row in the register based on the comparison result and the number of elements stored in the register.

6. The memory device of claim 5, wherein the register insertion control circuit is configured to store the care information for the aggressor row in the register when the access count value is less than the first threshold and greater than the second threshold and the number of elements stored in the register, which is received from the register monitor, is less than a preset care reference count.

7. The memory device of claim 5, wherein the row hammer control circuit further comprises a random number generator configured to probabilistically generate a random care determination value based on preset probability information and provide the random care determination value to the register insertion control circuit, and
wherein the register insertion control circuit is configured to store the care information for the aggressor row in the register when the access count value is less than the first threshold and greater than the second threshold, the number of elements stored in the register, which is received from the register monitor, is less than the preset care reference count, and the random care determination value is received from the random number generator.

8. The memory device of claim 1, wherein the comparator is configured to compare the access count value with an alert threshold that is greater than the first threshold, and
wherein the register insertion control circuit is configured to control the row care control circuit to refresh the plurality of victim rows adjacent to the aggressor row when the access count value is greater than the alert threshold.

9. The memory device of claim 1, wherein the row hammer control circuit further comprises a counter reset circuit configured to initialize the access count value stored in the counter after the care information is stored in the register.

10. The memory device of claim 1, wherein the access count value stored in the counter is increased in response to the memory device receiving an active command corresponding to the aggressor row from an external device.

11. The memory device of claim 2, wherein the care information further comprises a blast radius value of the aggressor row, and
wherein the row care control circuit is configured to refresh two victim rows that are physically adjacent to the aggressor row when the blast radius value is 1, and four victim rows that are physically adjacent to the aggressor row when the blast radius value is 2.

12. The memory device of claim 2, wherein the care information further comprises the access count value of the aggressor row, and
wherein the register is configured to store the care information in descending order from a largest access count value.

13. An operating method of a memory device including an aggressor row and a plurality of victim rows, the operating method comprising:
receiving an active command corresponding to the aggressor row;
increasing an access count value of a counter comprising a plurality of counter memory cells electrically connected to the aggressor row;
comparing the access count value with a first threshold;
comparing the access count value with a second threshold that is less than the first threshold;
storing care information corresponding to the aggressor row in a register based on a result of comparing the access count value with the first threshold and the second threshold; and
extracting the care information stored in the register in response to a row care command and refreshing the plurality of victim rows adjacent to the aggressor row.

14. The operating method of claim 13, wherein the storing of the care information corresponding to the aggressor row in the register comprises storing the care information for the aggressor row in the register when the access count value is greater than the first threshold.

15. The operating method of claim 13, wherein the storing of the care information corresponding to the aggressor row in the register comprises monitoring a number of elements stored in the register and comparing the number of elements stored in the register with a preset care reference count.

16. The operating method of claim 15, further comprising storing the care information for the aggressor row in the register when the access count value is less than the first threshold and greater than the second threshold and the number of elements stored in the register is less than the preset care reference count.

17. The operating method of claim 15, wherein the storing of the care information corresponding to the aggressor row in the register further comprises:
probabilistically generating a random care determination value based on preset probability information; and
storing the care information for the aggressor row in the register when the access count value is less than the first threshold and greater than the second threshold, the number of elements stored in the register is less than the preset care reference count, and the random care determination value is generated.

18. A memory device comprising:
a memory cell array comprising an aggressor row, a plurality of victim rows, and a counter that is configured to store an access count value of the aggressor row and comprises a plurality of counter memory cells electrically connected to the aggressor row; and
a row hammer control circuit comprising:
a register configured to store care information for the aggressor row;
a comparator configured to compare the access count value with a first threshold and a second threshold and output a comparison result, the first threshold being greater than the second threshold;
a register monitor configured to monitor a number of elements stored in the register and output the number of elements stored in the register;
a random number generator configured to probabilistically generate a random care determination value based on preset probability information and output the random care determination value;
a register insertion control circuit configured to store the care information in the register based on the comparison result, the number of elements stored in the register, and the random care determination value; and
a row care control circuit configured to extract the care information from the register in response to a row care command and refresh the plurality of victim rows adjacent to the aggressor row.

19. The memory device of claim 18, wherein the register insertion control circuit is configured to store the care information for the aggressor row in the register when the access count value is greater than the first threshold.

20. The memory device of claim 18, wherein the register insertion control circuit is configured to store the care information for the aggressor row in the register when the access count value is less than the first threshold and greater than the second threshold, the number of elements stored in the register, which is received from the register monitor, is less than the preset care reference count, and the random care determination value is received from the random number generator.
